(19) United States
(12) Patent Application Publication
(10) Pub. No.: US 2023/0319172 A1
(43) Pub. Date: Oct. 5, 2023

(54) DISPLAY DEVICE

(71) Applicant: Samsung Display Co., Ltd., Yongin-si (KR)

(72) Inventors: JAE-SOO JANG, Suwon-si (KR); SUNGYEON CHO, Hwaseong-si (KR); JUYEOP SEONG, Suwon-si (KR); HEE-KWON LEE, Asan-si (KR); JAEWON JEONG, Cheonan-si (KR)

(21) Appl. No.: 18/184,570

(22) Filed: Mar. 15, 2023

(30) Foreign Application Priority Data
Mar. 30, 2022 (KR) 10-2022-0039721

(51) Int. Cl. H04M 1/02

(52) U.S. Cl. CPC H04M 1/0237; H04M 1/0268; H04M 1/0214

(57) ABSTRACT

A display device includes a display panel including a first region and a second region arranged along a first direction, a cover layer below a rear surface of the display panel, and overlapping the first region, a first support layer below the rear surface of the display panel, overlapping the second region, and spaced apart from the cover layer along the first direction, a second support layer below the cover layer, overlapping the first region, and defining openings, and a first resin portion in a space between the cover layer and the first support layer.

### CROSS-REFERENCE TO RELATED APPLICATION

This application claims priority to and the benefit of Korean Patent Application No. 10-2022-0039721, filed on Mar. 30, 2022, in the Korean Intellectual Property Office, the entire contents of which are hereby incorporated by reference.

### BACKGROUND

### 1. Field

The present disclosure herein relates to a display device capable of a sliding operation.

### 2. Description of Related Art

A display device, such as a smart phone, a digital camera, a laptop computer, a navigation unit, a smart television provides images to a user through a display surface. The display device may include a display panel that generates the images.

With the recent technology development, display devices of various shapes are being developed. For example, foldable or rollable flexible display devices are being developed. Flexible display devices that may be deformed into various shapes are easy to carry, and thus, may improve user's convenience.

Among the flexible display devices, an expandable flexible display device may accommodate at least a portion of a display panel inside a case, or may withdraw the same outside the case using the folding properties of the display panel when suitable. Accordingly, a user may expand a display screen of the display device when suitable. However, the expandable flexible display device has a limitation in that the curvature may be visually recognized by a lower structure that supports the display panel.

### SUMMARY

The present disclosure provides a display device with improved surface quality by reducing or minimizing the visually recognized curvature of surface of a display panel.

One or more embodiments of the present disclosure provides a display device including a display panel including a first region and a second region arranged along a first direction, a cover layer below a rear surface of the display panel, and overlapping the first region, a first support layer below the rear surface of the display panel, overlapping the second region, and spaced apart from the cover layer along the first direction, a second support layer below the cover layer, overlapping the first region, and defining openings, and a first resin portion in a space between the cover layer and the first support layer.

The first resin portion may contact respective ends of the cover layer and the first support layer, the ends facing each other.

A thickness of the first resin portion may be uniform along the first direction.

A thickness of the first resin portion may decrease along the first direction.

A modulus of the first resin portion may be less than a modulus of the first support layer.

A thickness of the cover layer may be greater than a thickness of the first support layer.

The cover layer may include a material that is different from a material of the first support layer.

The first support layer and the second support layer may include a same material.

The first resin portion may be between the first support layer and the second support layer in plan view.

The openings may be arranged in a lattice form in plan view.

The display device may further include second resin portions respectively in the openings.

The display device may further include support bars below the second support layer, spaced apart along the first direction, and extending in a second direction crossing the first direction.

The display device may further include a resin layer filling spaces between the support bars.

The support bars might not overlap the openings in plan view.

The first region of the display panel may be folded with respect to an axis extending along a second direction crossing the first direction.

In one or more embodiments of the present disclosure, a display device includes a display panel including a display surface having a plane region, and a folding region adjacent to the plane region along a first direction, and a rear surface opposing the display surface, a cover layer below the rear surface and overlapping the folding region, a first support layer below the rear surface, overlapping the plane region, and spaced apart from the cover layer along the first direction, a first resin portion between the cover layer and the first support layer, and a case accommodating the display panel, the cover layer, and the first support layer, and configured to switch between a first mode and a second mode by a sliding operation, wherein at least a portion of the display surface is configured to be covered by, or exposed from, the case, such that an area of a portion in the folding region that is exposed from the case is greater in the second mode than in the first mode.

The display device may further include a second support layer accommodated in the case, below the cover layer, spaced from the first support layer in the first direction, and defining openings.

The display device may further include second resin portions respectively in the openings.

The display device may further include support bars in the case, arranged along the first direction below the second support layer, and extending a second direction crossing the first direction.

The case may include a first case and a second case, the second case being fixedly coupled to the display panel, and the first case being configured to move away from, or closer to, the second case along the first direction.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain aspects of the present disclosure. In the drawings:

FIG. 1A and FIG. 1B are perspective views of a display device according to one or more embodiments of the present disclosure;

FIG. 2A is a cross-sectional view of a display device according to one or more embodiments of the present disclosure corresponding to the line I-I′ of FIG. 1A;

FIG. 2B is a cross-sectional view of a display device according to one or more embodiments of the present disclosure corresponding to the line II-II′ of FIG. 1B;

FIG. 3 is an exploded perspective view of a display device according to one or more embodiments of the present disclosure;

FIG. 4 is a cross-sectional view of a display panel according to one or more embodiments of the present disclosure;

FIG. 5 is a plan view of a display panel according to one or more embodiments of the present disclosure;

FIG. 6A and FIG. 6B are cross-sectional views of a display device according to one or more embodiments of the present disclosure corresponding to the line III-III′ of FIG. 3; and

FIG. 7A to FIG. 7C are cross-sectional views of a display device according to one or more embodiments of the present disclosure corresponding to the line III-III′ of FIG. 3.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Hereinafter, a display device according to one or more embodiments of the present disclosure will be described with reference to the accompanying drawings.

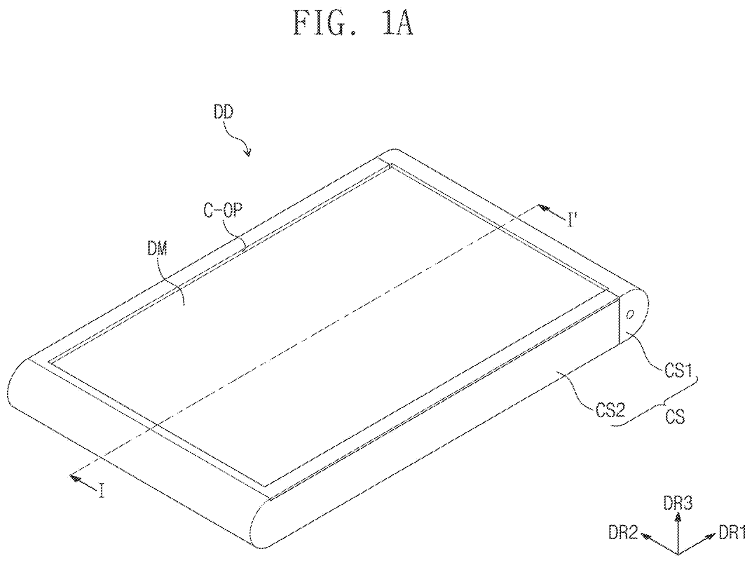

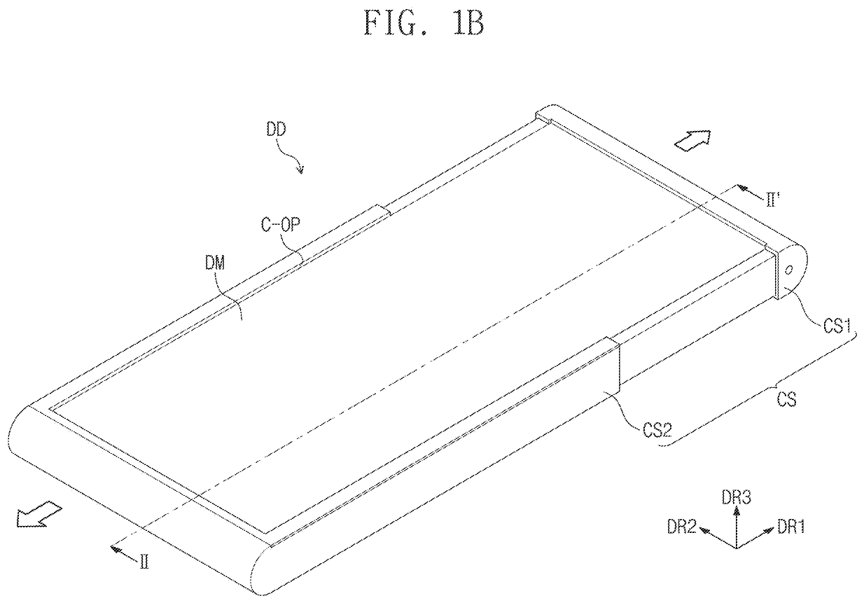

FIG. 1A and FIG. 1B are perspective views of a display device according to one or more embodiments of the present disclosure. FIG. 1A is a perspective view of the display device DD operating in a first mode, and FIG. 1B is a perspective view of the display device DD operating in a second mode.

The display device DD may be a device that is activated according to an electrical signal, and that displays images. The display device DD may include various embodiments. For example, the display device DD may be a large-sized device, such as a television or an external billboard, or a small-sized or medium-sized display device, such as a monitor, a smart phone, a tablet computer, a navigation unit, or a game console. In the present embodiments, the display device DD is illustrated as being a smart phone capable of a sliding operation.

Referring to FIG. 1A and FIG. 1B, the display device DD may include a display module DM, and a case CS in which the display module DM is accommodated. At least a portion of the display module DM may be exposed to the outside through a display opening C-OP defined in or by an upper portion of the case CS.

The case CS may include a first case CS1 and a second case CS2. The first case CS1 and the second case CS2 may be coupled to each other, and may accommodate the display module DM. The first case CS1 may be coupled to the second case CS2 so as to be movable in a direction substantially parallel to a first direction DR1. The first case CS1 may be coupled to the second case CS2, and may move closer toward or away from the second case CS2.

A display surface of the display module DM exposed by the display opening C-OP may be substantially parallel to each of the first direction DR1 and a second direction DR2 crossing the first direction DR1. The display module DM may display an image on the display surface parallel to the first direction DR1 and the second direction DR2 toward a third direction DR3.

In the present disclosure, the third direction surface DR3 may be defined as a direction substantially perpendicularly intersecting a plane defined by the first direction DR1 and the second direction DR2. The front surface (or upper surface) and the rear surface (or lower surface) of members (or units) constituting the display device DD may oppose each other in the third direction DR3, and the normal direction of each of the front surface and the rear surface may be substantially parallel to the third direction DR3. A separation distance between the front surface and the rear surface that is defined along the third direction DR3 may correspond to the thickness of a corresponding member (or unit).

In the present disclosure, “on a plane” may be defined as a state viewed in the third direction DR3. In the present disclosure, “on a cross-section” may be defined as a state viewed in the first direction DR1 or the second direction DR2. Meanwhile, directions indicated by the first to third directions DR1, DR2, and DR3 are a relative concept, and may be converted to different directions.

Referring to FIG. 1A and FIG. 1B, an area of the display surface of the display module DM exposed by the display opening C-OP may be adjusted as the first case CS1 moves. As the first case CS1 moves, an opening area of the display opening C-OP in a direction substantially parallel to the first direction DR1 may be changed.

The display module DM may be a flexible display module, and may be supported by a support layer located below the display module DM. When the first case CS1 moves along the first direction DR1, the support layer connected to the first case CS1 may move along the first direction DR1. In addition, an end of the display module DM located on the support layer may be connected to the first case CS1, and the display module DM may move along the first direction DR1 as the first case CS1 moves. As the display module DM moves, a portion of the display module DM accommodated in the second case CS2 may be exposed to the outside, and the display surface of the display module DM that is exposed through the display opening C-OP may be expanded.

FIG. 1A illustrates, among states of operation of the display device DD, the display device DD in the first mode, in which the first case CS1 and the second case CS2 are located to be closest in the first direction DR1. In the first mode, the other portion of the display module DM extended from the portion of the display module DM exposed by the display opening C-OP may be folded at a curvature (e.g., predetermined curvature), and may be accommodated in the second case CS2. The first mode in which the display surface of the display module DM is set to a basic size may be defined as a basic mode.

FIG. 1B illustrates, among states of operation of the display device DD, the display device DD in the second mode in which the first case CS1 and the second case CS2 are most spaced apart, or furthest from each other, in the first direction DR1. When the display device DD is switched from the first mode to the second mode, the area of the display surface of the display module DM that is exposed by the display opening C-OP may increase. That is, the second mode in which the display surface is expanded from the basic mode may be defined as an expansion mode.

The first mode and the second mode of the display device DD may be determined by the sliding operation of the case CS and the display module DM. As a user operates the display device DD from the first mode to the second mode, the display surface of the display device DD may be expanded, and through the expanded display surface, an image may be visually recognized. In addition, as the user operates the display device DD from the second mode to the first mode, the display surface of the display device DD may be reduced, and through the reduced display surface, an image may be visually recognized. That is, by selecting one between the first mode and the second mode, the user may adjust the area of the display surface of the display device DD exposed from the case CS in various ways.

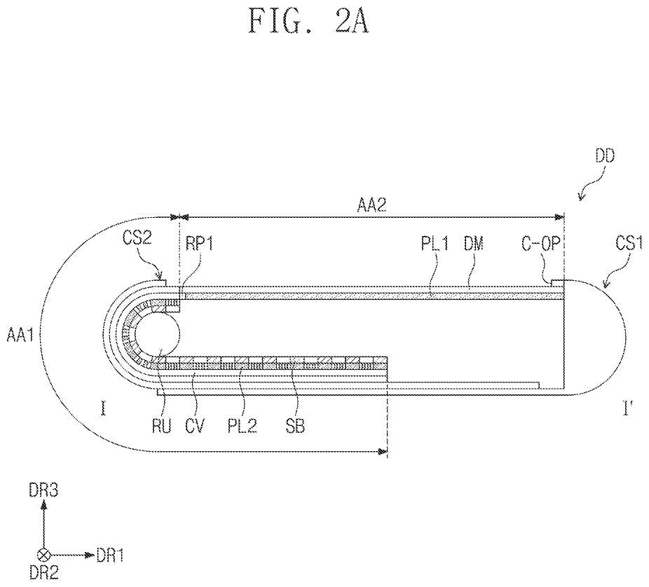

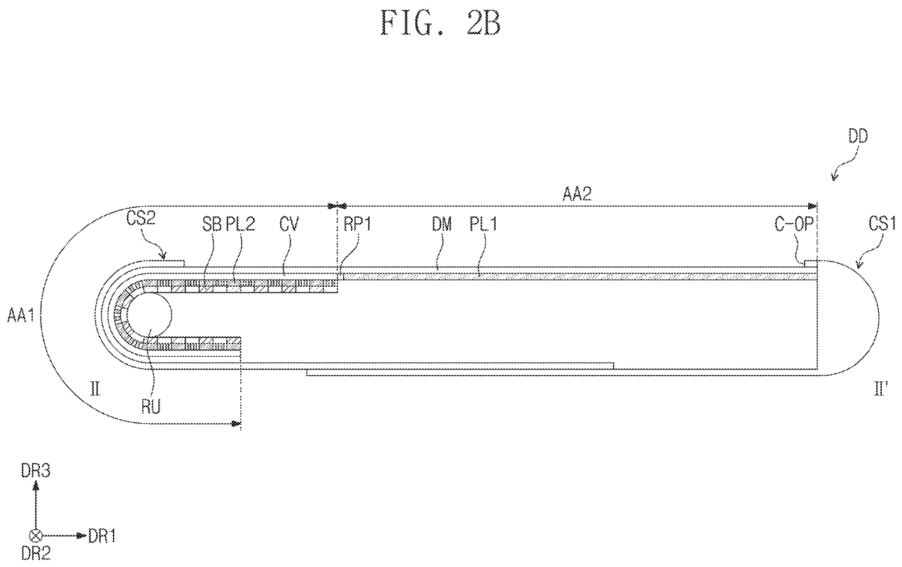

FIG. 2A is a cross-sectional view of a display device according to one or more embodiments of the present disclosure corresponding to the line I-I′ of FIG. 1A. FIG. 2B is a cross-sectional view of a display device according to one or more embodiments of the present disclosure corresponding to the line II-II′ of FIG. 1B. FIG. 2A corresponds to a cross-section of the display device DD in the first mode, and FIG. 2B correspond to a cross-section of the display device DD in the second mode.

Referring to FIG. 2A and FIG. 2B, the display device DD may include the case CS, the display module DM accommodated in the case CS, a rotating unit RU, and a support module located below the display module DM and supporting the display module DM. The support module that supports the display module DM may include a cover layer CV, a first resin portion RP1, a first support layer PL1, a second support layer PL2, and a plurality of support bars SB.

The display module DM may include a first region AM, and a second region AA2 extended from the first region AM along the first direction DR1. The first region AA1 may be a region supported by the cover layer CV and the second support layer PL2, and the second region AA2 may be a region supported by the first support layer PL1.

Referring to FIG. 2A, in the first mode, the display surface of the display module DM corresponding to the second region AA2 may be exposed to the outside. In the first mode, the second region AA2 may be provided parallel to the first direction DR1 and the second direction DR2, and the second region AA2 may be defined as a plane region. The first region AM may be folded such that an end thereof, which is spaced apart from the second region AA2, may overlap the second region AA2 in the third direction DR3. The first region AM may be defined as a folding region.

The rotating unit RU may be accommodated inside the second case CS2. The rotating unit RU may rotate around a rotation axis parallel to one direction. FIG. 2A and FIG. 2B illustrate the rotating unit RU rotatable around the rotation axis substantially parallel to the second direction DR2. The rotating unit RU is coupled to the second case CS2, and may rotate around the rotation axis in accordance with a sliding operation of either moving away from or closer to the second case CS2.

When the first case CS1 of FIG. 2A is moved away from the second case CS2 along the first direction DR1, the display device DD may be in the second mode illustrated in FIG. 2B. When the display device DD is operated from the first mode to the second mode, an end of the second region AA2 spaced apart from the first region AA1 may be coupled to, and may move along with the movement of, the first case CS1. At this time, the end of the first region AM spaced apart from the second region AA2 may move in a direction opposite from a moving direction of the end of the second region AA2 coupled to the first case CS1.

The cover layer CV, the second support layer PL2, and some of the support bars SB, all of which support the first region AA1 of the display module DM, may be located on a curved surface of the rotating unit RU and may be folded to have a curvature (e.g., predetermined curvature). As the display module DM moves when operated from the first mode to the second mode, the first region AA1, the cover layer CV, the second support layer PL2, and the support bars SB may move along the curved surface of the rotating unit RU. According to one or more embodiments, a portion of a display surface corresponding to the first region AA1 in the first mode may be exposed to the outside, and when operated from the first mode to the second mode, an area of a region in the first region AA1 that is exposed to the outside by the expansion of the display opening C-OP may be increased. However, the present disclosure is not limited thereto, and the display surface corresponding to the first region AA1 may be hidden the outside in the first mode.

In the first mode and the second mode, the mechanical properties required for a support module that supports the first region AA1 folded along the curved surface of the rotating unit RU, and for a support module that supports the second region AA2 maintaining a flat state in the first mode and the second mode, are different. Thus, the support modules may include different components. For example, the support module that supports the first region AA1 of the display module DM may be composed of the cover layer CV, the second support layer PL2, and the support bars SB, and the support module that supports the second region AA2 of the display module DM may be composed of the first support layer PL1.

Because the support module has different components depending on a region of the display module DM, there may be gaps between the components of the support module located side by side on a plane. For example, the cover layer CV and the first support layer PL1 that are located side by side on a plane may be spaced apart along the first direction DR1 due to separate, distinct components. That is, there may be a gap (or a space) between the cover layer CV and the first support layer PL1.

The first resin portion RP1 may be located in the space between the cover layer CV and the first support layer PL1. By filling the space between the cover layer CV and the first support layer PL1, the first resin portion RP1 may provide a flat upper surface to the display module DM, and may improve the surface quality of the display module DM. The cover layer CV, the first support layer PL1, the second support layer PL2, the support bars SB, and the first resin portion RP1 will be described in detail later with reference to the drawings.

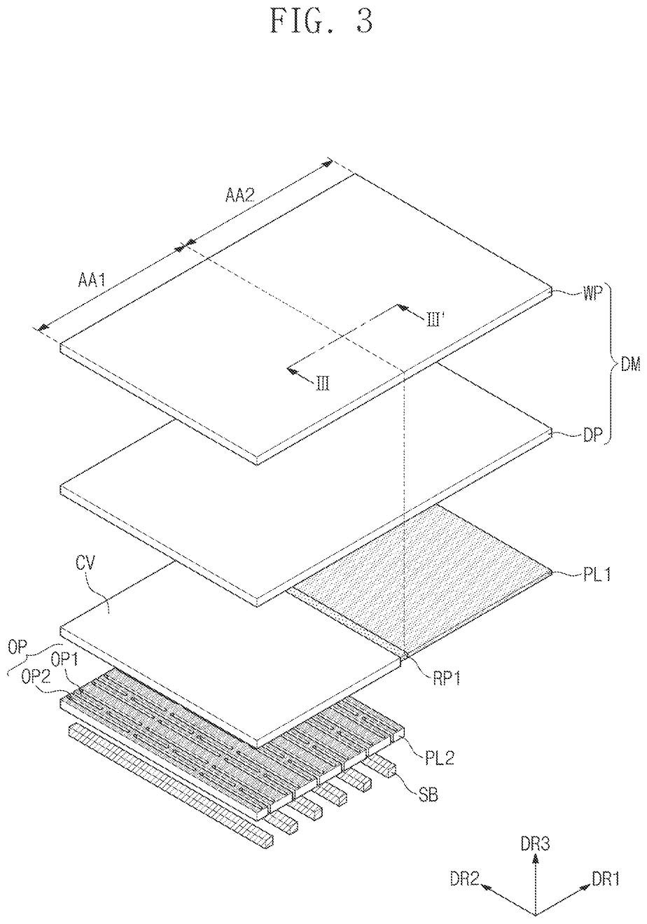

FIG. 3 is an exploded perspective view of a display device according to one or more embodiments of the present disclosure. For each component illustrated in FIG. 3, the description given above may be equally applied.

Referring FIG. 3, the display module DM may include a display panel DP, and a window WP located on the display panel DP. The window WP may substantially cover the entire upper surface of the display panel DP. The window WP may protect the display panel DP from external impacts and scratches.

The window WP may include an optically transparent insulation material. For example, the window WP may include a glass, a sapphire, or a polymer. The window WP may have a single-layered structure or a multi-layered structure. The window WP may further include a functional layer, such as an anti-fingerprint layer, a phase control layer, and a hard coating layer that are located on an optically transparent substrate.

Meanwhile, the configuration of the display module DM is not limited thereto, and functional layers that are located between the window WP and the display panel DP may be further included. For example, the display module DM may further include at least one of a protective layer, an anti-reflection layer, or an input sensing layer.

The display panel DP may include a first region AA1 and a second region AA2, which may correspond to the first region AA1 and the second region AA2 of the display module DM described above, and the same descriptions may be equally applied thereto. For convenience of description, FIG. 3 shows the first region AA1 and the second region AA2 on an upper surface of the window WP.

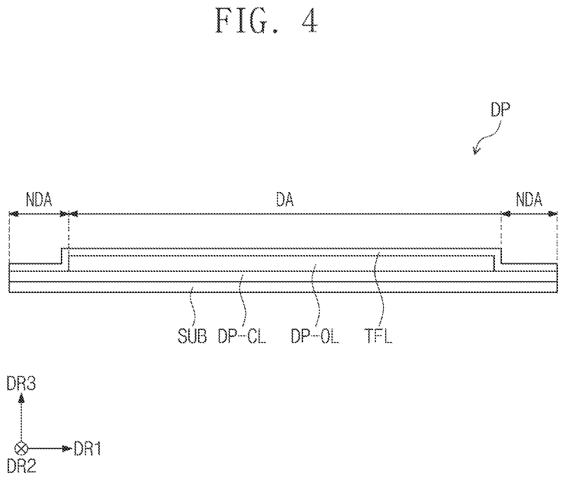

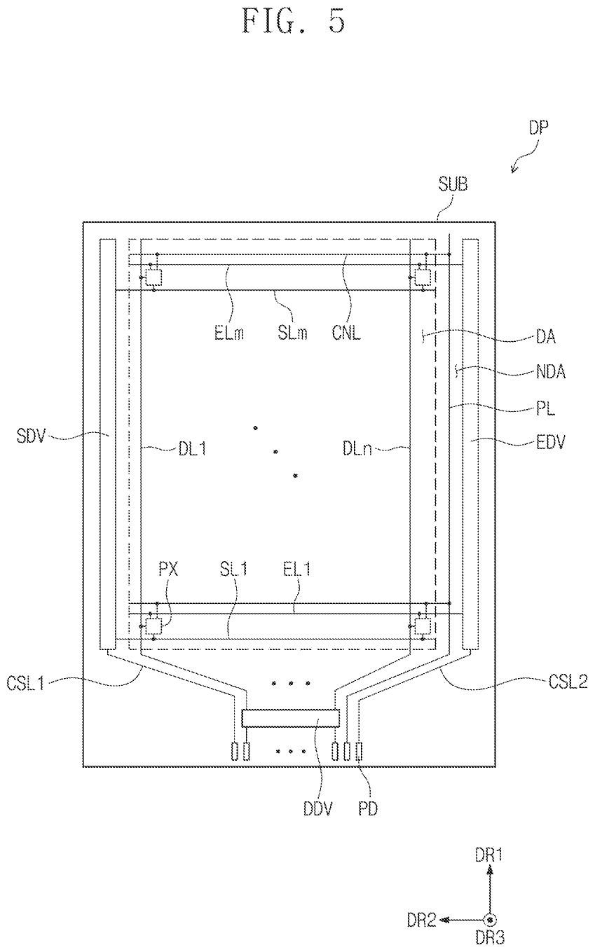

The display panel DP according to one or more embodiments may be a light emission-type display panel, but is not particularly limited. For example, the display panel DP may be an organic light emission display panel or an inorganic light emission display panel. A light emission layer of the organic light emission display panel may include an organic light emission material. A light emission layer of the inorganic light emission display panel may include a quantum dot, a quantum load, or the like. The display panel DP according to one or more embodiments will be described in detail with reference to FIG. 4 and FIG. 5.

The cover layer CV may be located on the rear surface of the display panel DP. The cover layer CV may overlap the first region AA1 of the display panel DP. In an unfolded state, the cover layer CV may be substantially parallel to each of the first direction DR1 and the second direction DR2. The cover layer CV may protect the rear surface of the display panel DP corresponding to the first region AA1, and may not overlap the second region AA2.

The cover layer CV may include a material having flexibility. For example, the cover layer CV may include a polymer material. By supporting the first region AA1 of the display panel DP folded at a curvature (e.g., predetermined curvature), the cover layer CV may relieve the stress caused by folding. The second region AA2 not folded in the first mode and the second mode does not require the relief of the stress caused by folding, so that the cover layer CV may not be located therein. Accordingly, a laminate structure of the display device DD corresponding to the second region AA2 may be simplified.

The first support layer PL1 may be located on the rear surface of the display panel DP. The first support layer PL1 may overlap the second region AA2 of the display panel DP. The first support layer PL1 may have a plate shape substantially parallel to both of the first direction DR1 and the second direction DR2. The first support layer PL1 may protect the rear surface of the display panel DP corresponding to the second region AA2, and may not overlap the first region AA.

The first support layer PL1 may include a material having a rigidity. For example, the first support layer PL1 may include stainless steel, aluminum, or an alloy thereof. However, the material of the first support layer PL1 is not limited thereto. The first support layer PL1 may support the rear surface of the display panel DP such that the second region AA2 of the display panel DP maintains a flat state in the first mode and in the second mode. In addition, the first support layer PL1 may improve the impact resistance of the display panel DP.

The cover layer CV may include a material that is different from that of the first support layer PL1. The first support layer PL1 may have a modulus that is greater than that of the cover layer CV. As long as the cover layer CV supports the first region AA1 of the display panel DP and relieves stress caused by folding, and as long as the first support layer PL1 supports the second region AA2 of the display panel DP to be flat, the cover layer CV and the first support layer PL1 are not particularly limited.

The cover layer CV and the first support layer PL1 may be located side by side to each other on the rear surface of the display panel DP. For example, an end of the cover layer CV may face an end of the first support layer PL1 along the first direction DR1. The cover layer CV may be spaced apart from the first support layer PL1 along the first direction DR1.

The first resin portion RP1 may be located in a space between the cover layer CV and the first support layer PL1. According to one or more embodiments of the present disclosure, the first resin portion RP1 may contact at least one of the cover layer CV and the first support layer PL1.

If the first resin portion RP1 is omitted, a step may be formed in the space between the cover layer CV and the first support layer PL1, and the step may be visually recognized from the outside. In addition, there may be a curvature on the upper surface of the display panel DP located on the cover layer CV and the first support layer PL1 due to the step. Because the first resin portion RP1 according to one or more embodiments of the present disclosure fills the space between the cover layer CV and the first support layer PL1, it is possible to reduce or prevent the likelihood of a step or curvature being visually recognized from the outside. In addition, the cover layer CV, the first resin portion RP1, and the first support layer PL1 that are sequentially located along the first direction DR1 may provide a substantially flat surface on the display panel DP, and the surface quality of the display panel DP may be improved.

The modulus of the first resin portion RP1 may be less than the modulus of the first support layer PL1. The first resin portion RP1 may include an elastic polymer having an elastic force. For example, the first resin portion RP1 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, or ethylene-vinyl acetate. However, the material of the first resin portion RP1 is not limited thereto.

The second support layer PL2 may be located below the cover layer CV. The second support layer PL2 may overlap the first region AA1 of the display panel DP. In an unfolded state, the second support layer PL2 may be substantially parallel to each of the first direction DR1 and the second direction DR2. The second support layer PL2 may not overlap the second region AA2. On a plane, or in plan view, the second support layer PL2 may be spaced apart from the first support layer PL1 with the first resin portion RP1 interposed therebetween.

The second support layer PL2 may include a material having a rigidity. As a result, the second support layer PL2 may improve the impact resistance of the display panel DP corresponding to the first region AA. For example, the second support layer PL2 may include stainless steel, aluminum, or an alloy thereof. In one or more embodiments, the second support layer PL2 and the first support layer PL1 may include the same material. However, the material of the second support layer PL2 is not limited thereto.

On the second support layer PL2, a plurality of openings OP penetrating the second support layer PL2 may be defined. The second support layer PL2 may be suitably folded to the openings OP. That is, the second support layer PL2 may be suitably folded at a curvature (e.g., predetermined curvature) by the openings OP while having rigidity.

Each of the openings OP may extend along the second direction DR2. That is, the width of each of the openings OP in the second direction DR2 may be greater than the width thereof in the first direction DR1. The openings OP may be arranged in a lattice form. Accordingly, in the second support layer PL2, a lattice pattern may be formed by the openings OP.

The openings OP may include first openings OP1 and second openings OP2 arranged shifted from each other in a direction substantially parallel to the first direction DR1. The first openings OP1 and the second openings OP2 may be arranged to form respective rows along the second direction DR2. However, this is only illustrated as an example, and the plurality of openings OP according to one or more embodiments of the present disclosure may all be arranged side by side along the first direction DR1, and are not particularly limited.

According to one or more embodiments illustrated in FIG. 3, the second openings OP2 arranged along the second direction DR2 may be located adjacent to respective sides of the first openings OP1 arranged along the second direction DR2. The first and second openings OP1 and OP2 constituting the above-described three rows may be defined as one group opening, and the group opening may be provided in plurality and arranged along the first direction DR1. However, this is only illustrated as an example, and the arrangement and interval of the openings OP may be variously designed according to the design of the second support layer PL2, and are not limited.

The support bars SB may be located below the second support layer PL2. Each of support bars SB may extend along the second direction DR2. The support bars SB may be spaced apart from each other along the first direction DR1. The support bars SB are provided as a segment such that the first region AA1 of the display panel DP may be suitably folded along the curved surface of the rotating unit RU (see FIGS. 2A and 2B).

The support bars SB may not overlap the openings OP of the second support layer PL2. As a result, the support bars SB may not degrade the folding properties of the second support layer PL2. However, the present disclosure is not limited thereto, and some of the support bars SB may overlap the openings OP.

The support bars SB may include a material having a rigidity. For example, the support bars SB may include a metal, such as aluminum, stainless steel, or an invar, or may include a carbon fiber. However, as long as the support bars SB are provided as a segment and support the first region AA1 of the display panel DP, the material thereof is not limited to the above examples.

FIG. 4 is a cross-sectional view of a display panel according to one or more embodiments of the present disclosure. FIG. 5 is a plan view of a display panel according to one or more embodiments of the present disclosure.

Referring to FIG. 4, the display panel DP may include a base substrate SUB, a circuit element layer DP-CL, a display element layer DP-OL, and an encapsulation layer TFL. The circuit element layer DP-CL, the display element layer DP-OL, and the encapsulation layer TFL may be sequentially laminated along the third direction DR3 on the base substrate SUB.

The base substrate SUB may provide a base surface on which elements and lines of the display panel DP are located on a plane parallel to each of the first direction DR1 and the second direction DR2. The base substrate SUB may include a display region DA and a non-display region NDA. The display region DA may be a region in which pixels are located to display an image. The non-display region NDA is adjacent to the display region DA, and may be a region in which the image is not displayed. The non-display region NDA may be a region in which lines connected to pixels for transmitting a driving signal are located.

The base substrate SUB may include a flexible plastic substrate. For example, the base substrate SUB may include at least one synthetic resin layer. The synthetic resin layer may include at least one of an acrylic resin, a methacryl-based resin, a polyisoprene-based resin, a vinyl-based resin, an epoxy-based resin, a urethane-based resin, a cellulose-based resin, a siloxane-based resin, a polyimide-based resin, a polyamide-based resin, or a polyimide-based resin. However, the material of the base substrate SUB is not limited thereto.

The circuit element layer DP-CL may be located on the base substrate SUB. The circuit element layer DP-CL may include at least one insulation layer, driving elements, signal lines, and signal pads. The circuit element layer DP-CL may include conductive patterns and semiconductor patterns for forming driving elements, signal lines, and signal pads.

The display element layer DP-OL may be located on the circuit element layer DP-CL. The display element layer DP-OL may include light emission elements overlapping the display region DA. The light emission elements of the display element layer DP-OL may be electrically connected to the driving elements of the circuit element layer DP-CL, and may generate light in the display region DA according to a signal provided by the driving elements.

The encapsulation layer TFL may be located on the display element layer DP-OL, and may encapsulate the light emission elements. The encapsulation layer TFL may include a plurality of thin films. The thin films of the encapsulation layer TFL may improve optical efficiency of the light emission element or may protect the light emission element. In one or more embodiments, the encapsulation layer TFL may include at least one inorganic film and at least one organic film. The inorganic film of the encapsulation layer TFL may protect the light emission element from moisture/oxygen. The organic film of the encapsulation layer TFL may protect the light emission element from foreign substances, such as dust particles.

Referring to FIG. 5, the display panel DP may include the base substrate SUB, a plurality of pixels PX, a plurality of signal lines SL1 to SLm, DL1 to DLn, EL1 to ELm, CSL1, CSL2, PL, and CNL electrically connected to the pixels PX, a scan driver SDV, a data driver DDV, and light emission driver EDV.

Each of the pixels PX may include a light emission element and a pixel driving circuit composed of a plurality of transistors (e.g., a switching transistor, a driving transistor, etc.) connected to the light emission element, and at least one capacitor.

The pixels PX may be located in the display region DA. Each of the pixels PX may emit light in correspondence to an electrical signal applied to the pixels PX. However, some of the pixels PX may include a transistor located in the non-display region NDA, and are not limited.

The scan driver SDV, the data driver DDV, and the light emission driver EDV may be located in the non-display region NDA. However, the present disclosure is not limited thereto, and at least one of the scan driver SDV, the data driver DDV, or the light emission driver EDV may be located in the display region DA, and as a result, the area of the non-display region NDA may be decreased.

The data driver DDV may be provided in the form of an integrated circuit chip, which is defined as a driving chip, and may be mounted in the non-display region NDA of the display panel DP. However, the present disclosure is not limited thereto, and the data driver DDV may be mounted on a separate flexible circuit board connected to the display panel DP, and may be electrically connected to the display panel DP

The signal lines SL1 to SLm, DL1 to DLn, EL1 to ELm, CSL1, CSL2, PL, and CNL may include scan lines SL1 to SLm, data lines DL1 to DLn, light emission lines EL1 to ELm, first and second control lines CSL1 and CSL2, a power line PL, and connection lines CNL. Here, m and n are natural numbers.

The data lines DL1 to DLn may cross the scan lines SL1 to SLm and the light emission lines EL1 to ELm while being insulated therefrom. For example, the scan lines SL1 to SLm may extend in the second direction DR2, and may be connected to the scan driver SDV. The data lines DL1 to DLn may extend in the first direction DR1 and may be connected to the data driver DDV. The light emission lines EL1 to ELm may extend in the second direction DR2 and may be connected to the light emission driver EDV.

The power line PL may extend in the first direction DR1 and may be located in the non-display region NDA. In one or more embodiments, the power line PL may be located between the display region DA and the light emission driver EDV. However, the location of the power line PL is not limited thereto.

The connection lines CNL may extend in the second direction DR2, and may be arranged in the first direction DR1 to be connected to the power line PL and the pixels PX. Each of the connection lines CNL may be located on a layer that is different from the layer on which the power line PL is located, and may be electrically connected thereto through a contact hole. However, the present disclosure is not limited thereto, and the connection lines CNL may be formed as one body with the power line PL on the same layer. A power voltage may be applied to the pixels PX through the power line PL and the connection lines CNL connected to each other.

The first control line CSL1 may be connected to the scan driver SDV. The second control line CSL2 may be connected to the light emission driver EDV.

Pads PD may be located adjacent to a lower end of the non-display region NDA. The pads PD may be located more adjacent to the lower end of the display panel DP than the data driver DDV. The pads PD may be spaced apart along the second direction DR2. The pads PD may be a portion to which a circuit board is connected, wherein the circuit board provides a signal to control the operation of each of the scan driver SDV, the data driver DDV, and the light emission driver EDV.

The pads PD may respectively be connected to a corresponding signal line among the signal lines. For example, the power line PL, the first control line CSL1, and the second control line CSL2 may respectively be connected to the pads PD. The data lines DL1 to DLn may be electrically connected to corresponding pads PD through the data driver DDV.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The light emission driver EDV may generate light emission signals in response to a light emission control signal. The light emission signals may be applied to the pixels PX through the light emission lines EL1 to ELm.

The pixels PX may be provided with the data voltages in response to the scan signals. The pixels PX may display an image by emitting light of luminance corresponding to the data voltages in response to the light emission signals. The light emission duration of the pixels PX may be controlled by the light emission signals. Accordingly, the display panel DP may output the image through the display region DA by the pixels PX.

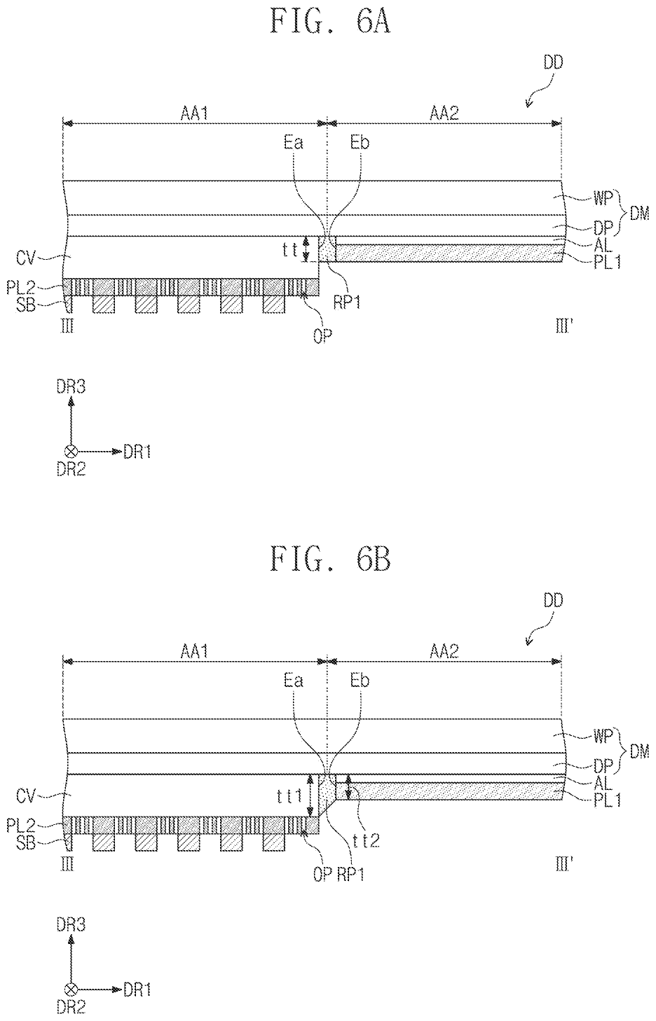

FIG. 6A and FIG. 6B are cross-sectional views of a display device according to one or more embodiments of the present disclosure corresponding to the line III-III′ of FIG. 3. The description of each component illustrated in FIG. 6A and FIG. 6B may be the same as described above, so that redundant descriptions will be mainly described.

Referring to FIG. 6A and FIG. 6B, the cover layer CV, the second support layer PL2, and support bars SB may be sequentially located on the rear surface of the display panel DP corresponding to the first region AA1, and may support the display panel DP. The first support layer PL1 may be located on the rear surface of the display panel DP corresponding to the second region AA2, and may support the display panel DP.

In one or more embodiments, the first support layer PL1 may be coupled on the rear surface of the display panel DP through an adhesive layer AL. The adhesive layer AL may include a clear adhesive, such as an optically clear adhesive (OCA) film, an optically clear resin (OCR), or a pressure sensitive adhesive (PSA) film. However, the type of the adhesive included in the adhesive layer AL is not limited thereto. Meanwhile, in one or more embodiments, the adhesive layer AL may be omitted.

The cover layer CV may be directly formed on the rear surface of the display panel DP. That is, the cover layer CV may contact the rear surface of the display panel DP. However, the present disclosure is not limited thereto, and the cover layer CV may be coupled to the rear surface of the display panel DP through a separate adhesive layer.

A thickness of the cover layer CV may be greater than a thickness of the first support layer PL1. The cover layer CV is relatively thick, and thus, may effectively absorb the stress applied to the display panel DP when the first region AA1 is folded.

The cover layer CV may be spaced apart from the first support layer PL1 along the first direction DR1. An end Ea of the cover layer CV may face an end Eb of the first support layer PL1 along the first direction DR1. The first resin portion RP1 may fill a space between the cover layer CV and the first support layer PL1. In the present embodiments, the first resin portion RP1 may contact each of the one end Ea of the cover layer CV and the one end Eb of the first support layer PL1. According to one or more embodiments of the present disclosure, the first resin portion RP1 may contact the adhesive layer AL located on the first support layer PL1.

The first resin portion RP1 may be formed while having a thickness tt. As illustrated in FIG. 6A, the thickness tt of the first resin portion RP1 may be uniform along the first direction DR1. The first resin portion RP1 may entirely cover the one end Eb of the first support layer PL1 (e.g., may cover the side of the one end Eb of the first support layer PL1). FIG. 6A illustrates that the thickness tt of the first resin portion RP1 corresponds to the sum of the thickness of the first support layer PL1 and a thickness of the adhesive layer AL, but the present disclosure is not limited thereto. For example, the thickness tt of the first resin portion RP1 may correspond to the thickness of the cover layer CV, and may entirely cover the one end Ea of the cover layer CV (e.g., may cover the side of the one end Ea of the cover layer CV), or may be less than the thickness of the first support layer PL1.

As illustrated in FIG. 6B, thicknesses tt1 and tt2 of the first resin portion RP1 may change along the first direction DR1. The thicknesses tt1 and tt2 of the first resin portion RP1 may be reduced closer to the first support layer PL1 from the cover layer CV (e.g., the thickness of the first resin portion RP1 may gradually reduce from the cover layer CV to the first support layer PL1). That is, the thickness tt1 of one end of the first resin portion RP1 adjacent to the cover layer CV may be different from the thickness tt2 of the other end of the first resin portion RP1 adjacent to the first support layer PL1. Accordingly, the first resin portion RP1 may entirely cover the one end Ea of the cover layer CV (e.g., the side of the one end Ea of the cover layer CV) and the one end Eb of the first support layer PL1 (e.g., the side of the one end Eb of the first support layer PL1).

Meanwhile, the thickness of the first resin portion RP1 is not limited as long as the space between the cover layer CV and the first support layer PL1 can be filled.

Referring to FIG. 6A and FIG. 6B, when viewed from the second direction DR2, which is substantially parallel to a direction in which the support bars SB are extended, the shapes of the support bars SB on a cross-section may be quadrangular. That is, each of the support bars SB may include an upper surface facing the display panel DP, and a rear surface opposing the upper surface, and an area of the upper surface and an area of the rear surface may be the same. However, this is only illustrated as an example, and each of the support bars SB may include a rear surface that has a smaller area than an upper surface of the support bars SB. For example, on a cross-section, the shapes of the support bars SB may be an inverted triangle, or an inverted trapezoid. As long as the support bars SB are provided as a segment on the rear surface of the display panel DP, and as long as the support bars SB support the display panel DP, the shapes thereof are not limited.

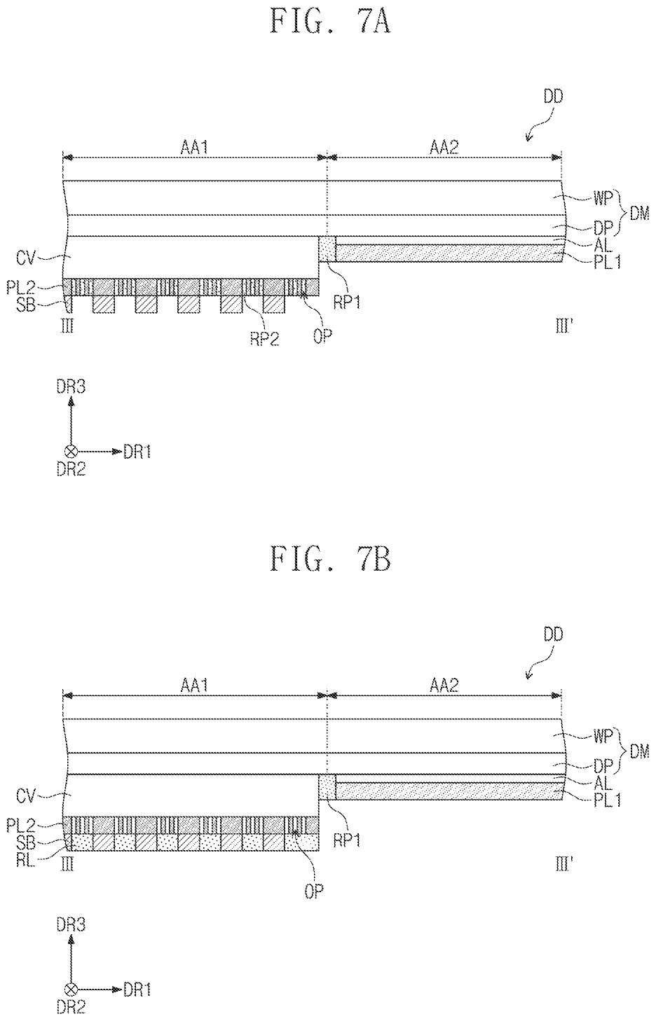

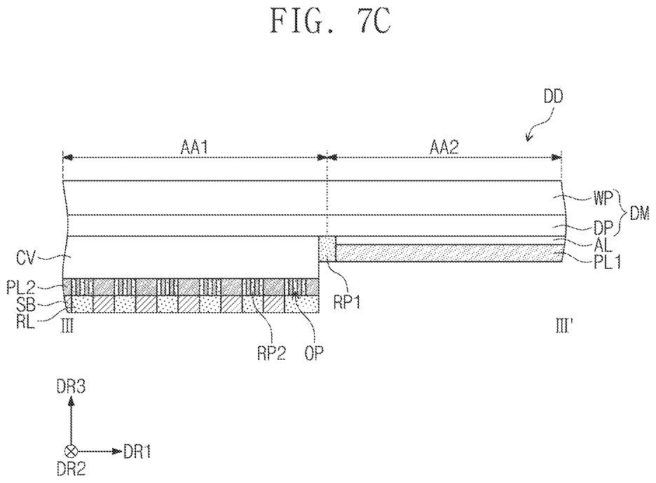

FIG. 7A to FIG. 7C are cross-sectional views of a display device according to one or more embodiments of the present disclosure corresponding to the line III-III′ of FIG. 3. The description of each component illustrated in FIG. 7A to FIG. 7B may be the same as described above, so that redundant descriptions will be mainly described.

Referring to FIG. 7A, the display device DD may further include a plurality of second resin portions RP2. The second resin portions RP2 may be respectively located in the openings OP of the second support layer PL2. That is, the second resin portions RP2 may be filled in spaces of the openings OP. By including the second resin portions RP2, the second support layer PL2 may provide a substantially flat surface, and may improve the surface quality of the display panel DP corresponding to the first region AA1 and the surface quality of the display device DD.

A modulus of the second resin portion RP2 may be less than a modulus of the second support layer PL2. The second resin portions RP2 may include an elastic polymer having an elastic force, and may be suitably folded while having a curvature (e.g., predetermined curvature). Accordingly, the second resin portions RP2 may not degrade the folding properties of the second support layer PL2, and may fill the openings OP.

Referring FIG. 7B, the display device DD may further include a resin layer RL. The resin layer RL and the support bars SB may be located on the same layer. For example, the resin layer RL and the support bars SB may be located on the rear surface of the second support layer PL2.

The resin layer RL may fill separation spaces between the support bars SB. For example, the resin layer RL may be provided as a plurality of portions spaced apart with the support bars SB interposed therebetween, and the plurality of portions may respectively contact with side surfaces of adjacent support bars SB and fill spaces between the support bars SB. However, the present disclosure is not limited thereto, and the resin layer RL may be provided as a single layer that covers the upper surface and side surface of each of the support bars SB. That is, the support bars SB may be inserted into the resin layer RL.

The support bars SB may not overlap the openings OP of the second support layer PL2. The resin layer RL filled between the support bars SB may overlap the openings OP.

By filling the separation spaces between the support bars SB, the resin layer RL may cover steps formed between the support bars SB, and may provide a flat upper surface together with the support bars SB. Accordingly, the resin layer RL may improve the surface quality of the display panel DP corresponding to the first region AA1 and the surface quality of the display device DD.

A modulus of the resin layer RL may be less than a modulus of each of the support bars SB. The resin layer RL may include an elastic polymer having an elastic force, and may be suitably folded while having a curvature (e.g., predetermined curvature). Accordingly, the resin layer RL may connect the support bars SB that are segmented, and at the same time, may not degrade the folding properties.

Referring to FIG. 7C, the display device DD may further include the second resin portions RP2 located in the openings OP of the second support layer PL2, and the resin layer RL filled between the support bars SB. The resin layer RL may overlap the second resin portions RP2. The same description described above may be equally applied to the second resin portions RP2 and the resin layer RL.

The second resin portions RP2 or the resin layer RL may include the same material as that of the first resin portion RP1. However, the present disclosure is not necessarily limited thereto, and the first resin portion RP1, the second resin portions RP2, and the resin layer RL may include different materials from each other.

The second resin portions RP2 and the resin layer RL may each include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, or ethylene-vinyl acetate. However, the material of the second resin portions RP2 and the material of the resin layer RL are not limited thereto.

A display device of the present disclosure may include a support module having laminate structures different from each other depending on a region of a display panel, and may include a resin portion for filling a gap (or a space) between components of the support module. The resin portion may reduce or prevent steps between the components of the support module, and may provide a flat upper surface to the display panel located on the support module. As a result, it is possible to reduce or prevent the likelihood of a step or curvature being visually recognized from the outside of the display device. Accordingly, the present disclosure may provide the display device with improved surface quality.

A display device of the present disclosure includes a resin portion that fills a space between a support layer for supporting a plane region of a display panel, and a cover layer for protecting a folding region, and thus, may reduce or minimize steps of lower components of the display panel.

The display device of the present disclosure may have reduced or minimized curvature visually recognized from the outside, and may have improved surface quality.

Although the present disclosure has been described with reference to preferred embodiments of the present disclosure, it will be understood by those skilled in the art that various modifications and changes in form and details may be made therein without departing from the spirit and scope of the present disclosure as set forth in the following claims. Accordingly, the technical scope of the present disclosure is not intended to be limited to the contents set forth in the detailed description of the specification, but is intended to be defined by the appended claims, with functional equivalents thereof to be included therein.

What is claimed is:

1. A display device comprising:
a display panel comprising a first region and a second region arranged along a first direction;
a cover layer below a rear surface of the display panel, and overlapping the first region;
a first support layer below the rear surface of the display panel, overlapping the second region, and spaced apart from the cover layer along the first direction;
a second support layer below the cover layer, overlapping the first region, and defining openings; and
a first resin portion in a space between the cover layer and the first support layer.

2. The display device of claim 1, wherein the first resin portion contacts respective ends of the cover layer and the first support layer, the ends facing each other.

3. The display device of claim 1, wherein a thickness of the first resin portion is uniform along the first direction.

4. The display device of claim 1, wherein a thickness of the first resin portion decreases along the first direction.

5. The display device of claim 1, wherein a modulus of the first resin portion is less than a modulus of the first support layer.

6. The display device of claim 1, wherein a thickness of the cover layer is greater than a thickness of the first support layer.

7. The display device of claim 1, wherein the cover layer comprises a material that is different from a material of the first support layer.

8. The display device of claim 1, wherein the first support layer and the second support layer comprise a same material.

9. The display device of claim 1, wherein the first resin portion is between the first support layer and the second support layer in plan view.

10. The display device of claim 1, wherein the openings are arranged in a lattice form in plan view.

11. The display device of claim 1, further comprising second resin portions respectively in the openings.

12. The display device of claim 1, further comprising support bars below the second support layer, spaced apart along the first direction, and extending in a second direction crossing the first direction.

13. The display device of claim 12, further comprising a resin layer filling spaces between the support bars.

14. The display device of claim 12, wherein the support bars do not overlap the openings in plan view.

15. The display device of claim 1, wherein the first region of the display panel is folded with respect to an axis extending along a second direction crossing the first direction.

16. A display device comprising:
a display panel comprising:
a display surface having a plane region, and a folding region adjacent to the plane region along a first direction; and
a rear surface opposing the display surface;
a cover layer below the rear surface and overlapping the folding region;
a first support layer below the rear surface, overlapping the plane region, and spaced apart from the cover layer along the first direction;
a first resin portion between the cover layer and the first support layer; and
a case accommodating the display panel, the cover layer, and the first support layer, and configured to switch between a first mode and a second mode by a sliding operation,
wherein at least a portion of the display surface is configured to be covered by, or exposed from, the case, such that an area of a portion in the folding region that is exposed from the case is greater in the second mode than in the first mode.

17. The display device of claim 16, further comprising a second support layer accommodated in the case, below the cover layer, spaced from the first support layer in the first direction, and defining openings.

18. The display device of claim 17, further comprising second resin portions respectively in the openings.

19. The display device of claim 17, further comprising support bars in the case, arranged along the first direction below the second support layer, and extending a second direction crossing the first direction.

20. The display device of claim 16, wherein the case comprises a first case and a second case, the second case being fixedly coupled to the display panel, and the first case being configured to move away from, or closer to, the second case along the first direction.
